(19) United States
(12) Patent Application Publication
(10) Pub. No.: US 2005/0018393 A1
(43) Pub. Date: Jan. 27, 2005

(54) Magnetic open/close structure for electronic device

(75) Inventors: Wen-Chieh Kuo, Taipei City (TW); Yu-Yu Chen, Sinjhuang City (TW)

Correspondence Address: TROXELL LAW OFFICE PLLC, SUITE 1404, 5205 LEESBURG PIKE, FALLS CHURCH, VA, 22041, US

(73) Assignee: Uniwill Computer Corp.

(21) Appl. No.: 10/626,659

(22) Filed: Jul. 25, 2003

(51) Int. Cl. H05K 5/00

(52) U.S. Cl. 361/683

(57) ABSTRACT

A magnetic open/close structure for an electronic device such as a notebook computer is comprised of a primary magnet and an attachment to be attracted respectively provided on one side the lid and fixed at a specific place, a secondary magnet having the same polarity facing to that of the primary magnet being fixed by the side of the attachment; the primary magnet sliding back and forth at where it is overlapped with the attachment or the secondary magnet due to the motion of limited slide from the push key to provide a secure positioning structure for the lid when covering on the case; and the lid being ejected for a certain angle from the case for easy access to open it up by taking advantage of the rejection between the primary and the secondary magnets when the primary magnet is pushed to be overlapped with the secondary magnet.

### BACKGROUND OF THE INVENTION

(a) Field of the Invention

The present invention is related to a magnetic open/close structure for electronic device, and more particularly to a positioning structure provided between a lid and a case of a 3C electronic device including notebook computer and electronic translator to facilitate opening or closing the lid by taking advantage of magnetism.

(b) Description of the Prior Art

As illustrated in FIG. 1 of the accompanying drawings, a display of a notebook computer is provided in a lid (20) hinged at its bottom to a case (10) of the notebook computer. The lid (20) is lifted for normal operation or closed onto the case (10) when the notebook computer is not used to protect the display. Similar protection for the display is applied in electronic translator, cellular phone, PDA and other 3C electronic devices.

Though the lid adapted to a 3C electronic device provides a certain protection, a positioning means is required between the lid (20) and the case (10) to avoid damage by accidental opening of the lid (20). The positioning means of the prior art, as illustrated, is essentially comprised of a hook (30) protruding from the front frame of the lid adapted with a push key (80) to drive the hook (30) to slide, and a matching slit (11) provided on the front of the case (10). Upon closing the lid (20) onto the case (10), the hook (30) engages into the slit (11) to lock up the lid (20) and the case (10) to each other. To open up the lid (20), the push key (80) is pushed to drive the hook (30) to slide, thus to be released from the slit (11).

However, when the notebook computer is in use, the lid (20) is opened up leaving the slit (11) on the case (10) exposed to attract sweats, dust and other foreign matters that are difficult to be removed, and the hook (30) is also exposed to compromise the integral appearance of the notebook computer. The positioning means of the prior art though allows the lid (20) to be opened up once the hook (30) is disengaged from the slit (11), it prevents an easy access for the finger to reach the push key (80) since the lid (20) remains being locked up to the case. Furthermore, the hook (30) may be broken up due to improper application of external force during the transit or handling of the notebook computer to fail the expected result of positioning. The display is also prevented from appearing in full size on the lid (20) to spare certain space for the hook (30).

### SUMMARY OF THE INVENTION

The primary purpose of the present invention is to provide a magnetic open/close structure for an electronic device. To achieve the purpose, a primary magnet and an attachment to be attracted by the primary magnet are respectively provided on the frames of the lid and the case. Wherein, a the attachment is fixed at a specific location and a secondary magnet is fixed by the attachment with the same polarity close to each other. The primary magnet slides back and forth between it is overlapped with the attachment or the secondary magnet in a limited sliding motion provided by a push key. Accordingly, when the lid covers upon the case, the primary magnet attracts the attachment to become a positioning structure to ensure a proper closing of the lid upon the case. To lift the lid, the primary magnet is pushed to where it is overlapped with the secondary magnet to facilitate opening the lid by taking advantage of the working principal of the rejection between two magnets of same polarity to eject the lid for a certain lifting angle from the case.

Furthermore, a slide way is preset either in the frame of the lid or the case to accommodate the push key with the primary magnet being fixed inside the section of the lid or the case where the push key is embedded. Meanwhile, both of the attachment and the secondary magnet are relatively embedded in the case or the lid to hide the positioning structure from sight for improved aesthetic sense of the electronic device as a whole, thus to upgrade its expected value.

### BRIEF DESCRIPTION OF THE DRAWINGS

FIG. 1 is a view showing an appearance of a notebook computer provided with an open/close structure of the prior art.

FIG. 2 is a view showing an appearance of a notebook computer provided with a magnetic open/close structure of the present invention.

FIG. 3 is an exploded view of magnetic open/close structure of the present invention.

FIG. 4 is a sectional view showing a lid covering up a case of the present invention.

FIG. 5 is a schematic view showing a blowout of a location where a primary magnet and an attachment of the present invention when the lid covers up the case.

FIG. 6 is a sectional view showing that the primary magnet and a secondary magnet are overlapped.

FIG. 7 is an exploded view showing the magnetic open/close structure of another preferred embodiment of the present invention.

FIG. 8 is a blowout showing a local part taken from FIG. 7.

FIG. 9 is a schematic view showing a layout of the magnetic open/close structure of another preferred embodiment yet of the present invention.

FIG. 10 a schematic view showing a layout of the magnetic open/close structure of a further preferred embodiment yet of the present invention.

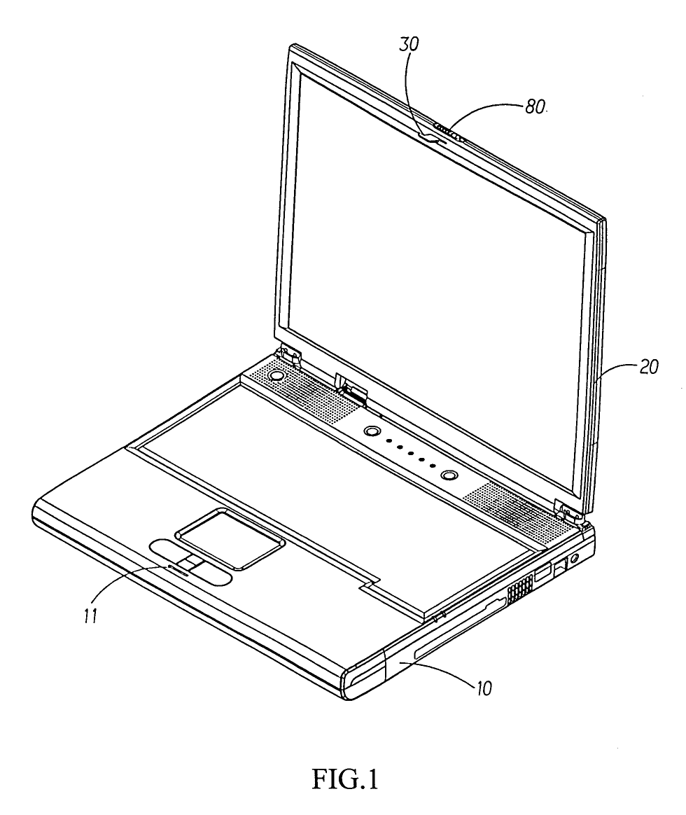

### DETAILED DESCRIPTION OF THE PREFERRED EMBODIMENTS

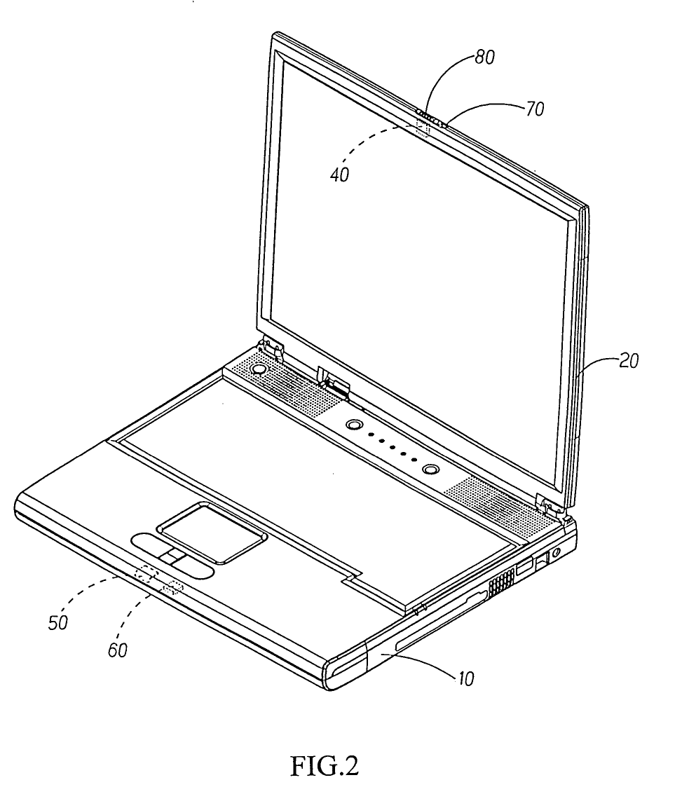

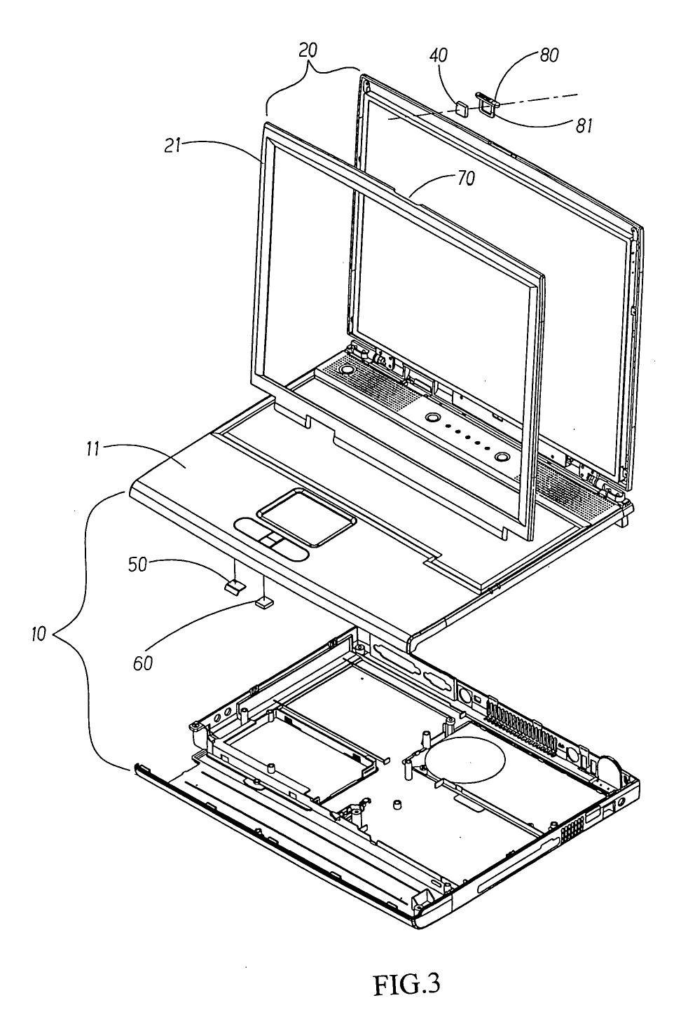

A magnetic open/close structure of an electronic device of the present invention relates to an improved positioning structure located between a lid and a case of a 3C electronic device provided with a lid such as notebooks and electronic translators generally available in the market. As illustrated in FIGS. 2 and 3 where the present invention is applied to a notebook, a primary magnet (40) with powerful magnetism and an attachment (50) made of a piece of galvanized steel are respectively provided on a frame of a lid (20) and another frame of a case (10) and a secondary magnet (60) is fixed by the side of the attachment (50) with the same polarity facing to the primary magnet (40).

In a preferred embodiment as illustrated in FIGS. 2 and 3, a slide way (70) is preset in the frame of the lid (20) and a push key (80) is provided to slide in the slide way (70) and a recess (81) to catch the primary magnet (40) in position is provided in the section of the lid (20) where the push key (80) is embedded for the primary magnet (40) to be fixed in the recess (81) in the frame of the lid (20) where the push key (80) is embedded. Both of the attachment (50) and the secondary magnet (60) are fixed to the front frame of the case (10). The case (10) is flushed to the lid (20) with an upper case cover (11) to allow the attachment (50) and the secondary magnet (60) to be fixed to the inner side of the upper case cover (11) of the case (10) by means of a secured method such as fusion or locking. Consequently, the attachment (50) and the secondary magnet are embedded inside the case (10) while the primary magnet slides back and forth at where it is overlapped with the attachment (50) or the secondary magnet (60) in a limited sliding motion provided by the push key (80).

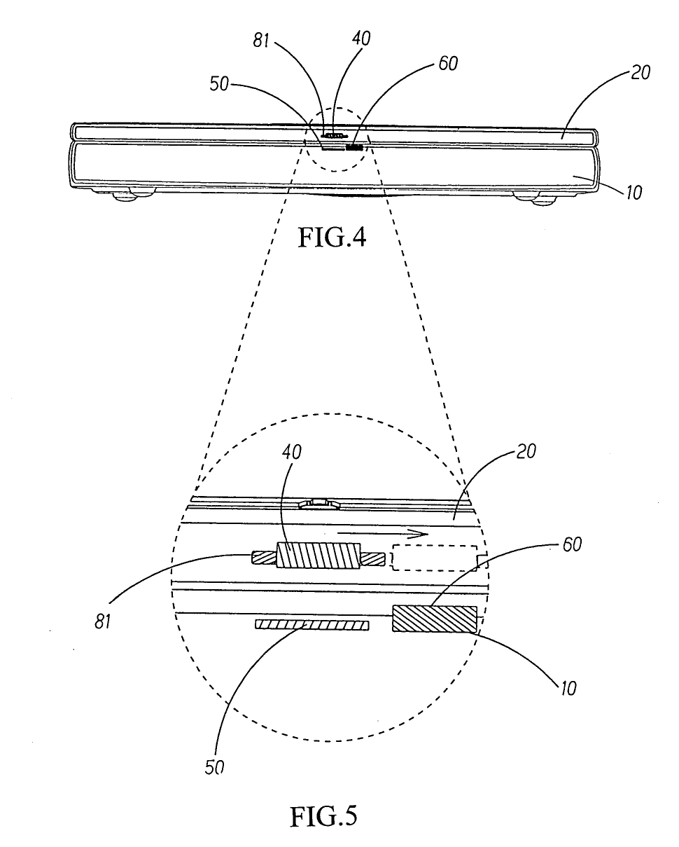

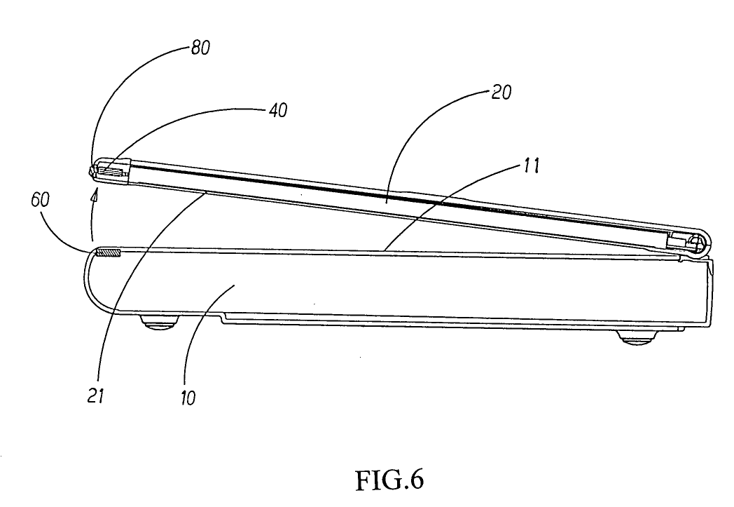

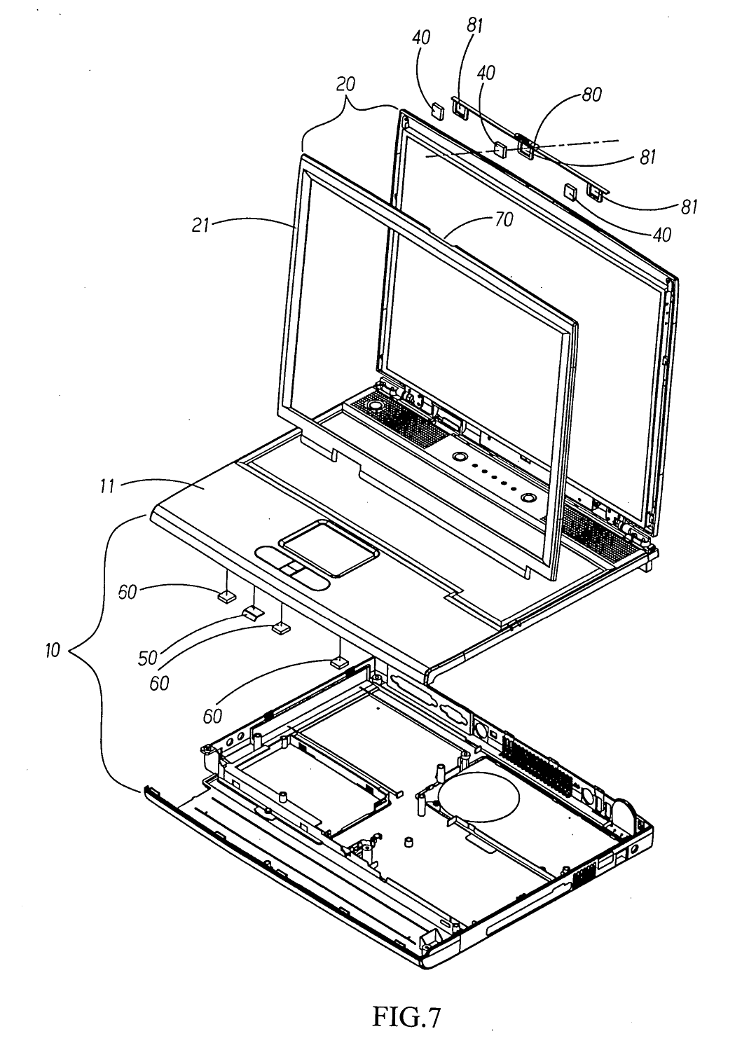

Accordingly, when the lid (20) covers upon the case (10) as illustrated in FIGS. 4 and 5, the attraction between the primary magnet (40) and the attachment (50) forces both of the primary magnet (40) and the attachment (50) to overlap for the lid (20) to firmly secure the case (10) in position. To lift the lid (20), the primary magnet (40) is pushed to where it is overlapped with the secondary magnet (60) as illustrated in FIG. 6, the rejection between the primary magnet (40) and the secondary magnet (60) ejects the lid (20) to open up for a certain angle from the case (10) to admit a finger to open up the lid (20).

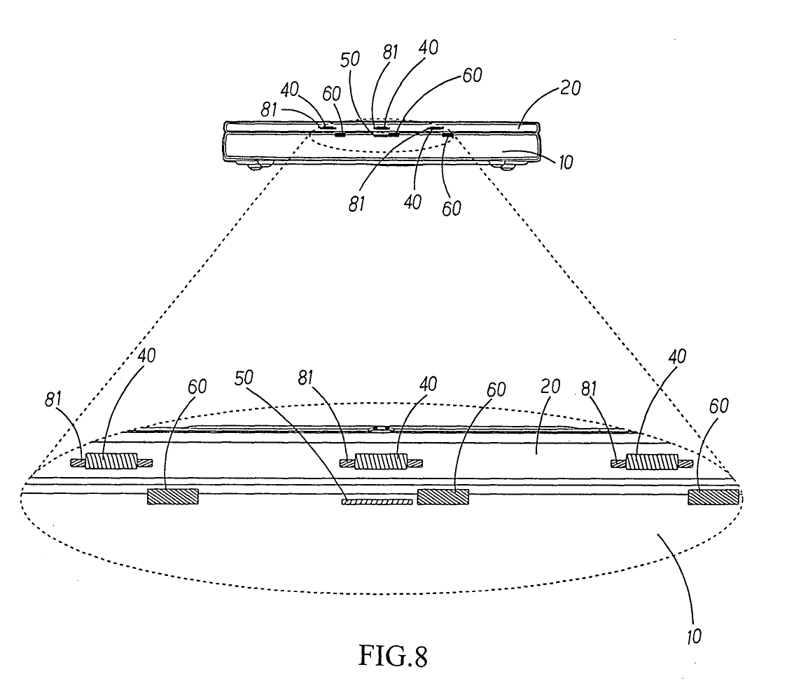

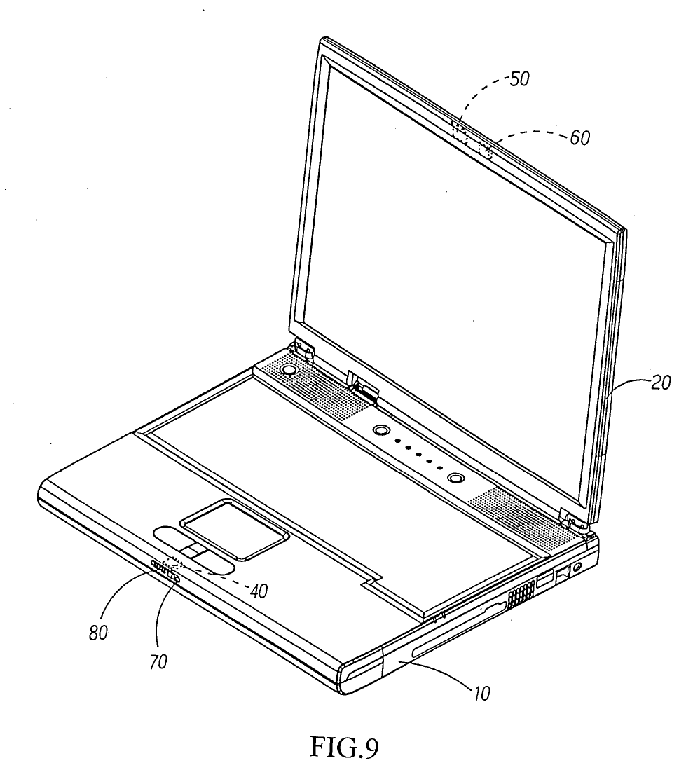

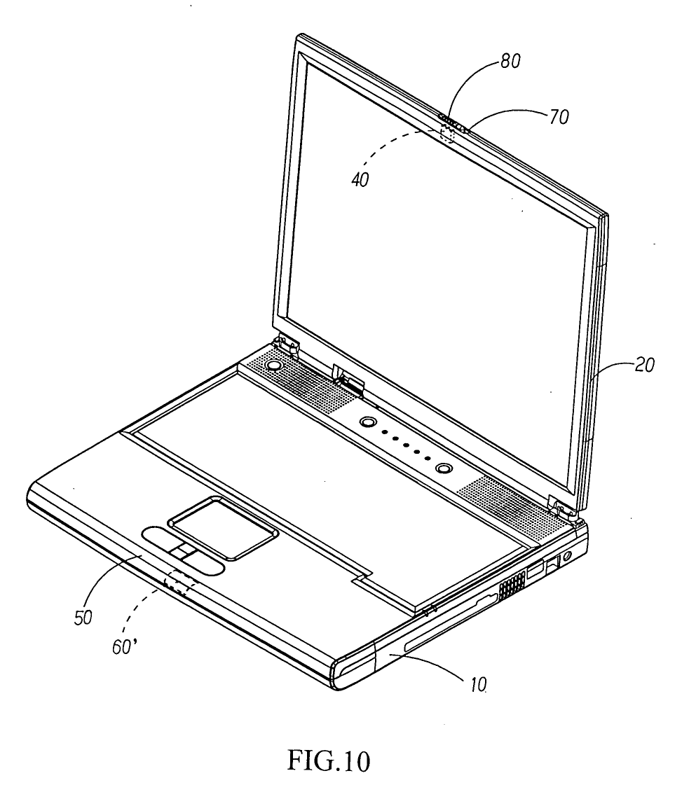

Now referring to FIG. 7, one or more than one primary magnet (40) is fixed to the section where the push key (80) is embedded inside the case (10) and corresponding attachment (50) and secondary magnet (60) in the same quantity as that of the primary magnet are provided inside the case (10) to further improve the consistent close and ejection results between the lid (20) and the case (10) as illustrated in FIG. 8. Furthermore, as illustrated in FIG. 9, the attachment (50) and the secondary magnet (60) are secured (by means of fusion in this preferred embodiment) to the inner side of a front frame (21) where the lid (20) is flushed with the case (10) to hide both of the attachment (50) and the secondary magnet (60) inside the lid (20). A slid way (70) is preset in the case (10) and the push key (80) slides in the slide way (70) for the primary magnet (40) to be fixed to the section where the push key (80) is embedded in the case (10) to provide the similar positioning structure for the lid (20). More than one primary magnet (40) may be provided in the section where the push key (80) is embedded in the case (10) with both of the attachment and the secondary magnet provided in the same quantity as that of the primary magnet to further improve the consistent close and ejection results between the case and the lid.

If the face panel of the case (10) is made of metallic material as illustrated in FIG. 10, it is directly constitute the attachment (50), and a specific section on one side of the frame of the case (10) at where relatively to the primary magnet (40) is locally magnetized to define a magnetized area (60′). The magnetized area (60′) constitutes a secondary magnet mutually inductive to the primary magnet. In another preferred embodiment illustrated in FIG. 10, the primary magnet is provided on one side of the frame of the lid (20) for the attraction between the primary magnet (40) and the metallic case (10) to constitute a positioning structure to secure cover up the lid (20) e case (10). To life the lid (20), the magnet (40) is pushed to where it is overlapped with the magnetized area (60′) to take advantage of the rejection between the primary magnet (40) and the magnetized area (60′) to eject the lid (20) for a certain angle from the case (10) to facilitate the finger to poke in for opening up the lid.

The present invention by having a magnetic open/close structure to secure the close of the lid upon the case and facilitates the open of the lid from the case for an electronic device provides an improved positioning structure for the electronic device provided with a lid. Therefore, this application for a utility patent is duly filed. However it should be noted that any and all the preferred embodiments and accompanying drawings disclosed herein do not in any way limit the present invention; therefore, any structure, means and/or characteristics that are identical with or similar to those of the prevent invention shall be deemed as falling within the purposes and claims of the present invention.

1. A magnetic open/close structure for an electronic device, is essentially comprised of a primary magnet and an attachment to be attracted by the primary magnet being respectively provided to the frame of a lid and a frame of the case with the attachment being fixed at a specific location; a secondary magnet having the same polarity facing that of the primary magnet being provided by the side of the attachment; a push key to provide a limited sliding motion for the primary magnet to slide back and forth at where it is overlapped with the attachment or the secondary magnet; the primary magnet being overlapped with the attachment by magnetism when the lid covers upon the case to secure the lid on the case.

2. A magnetic open/close structure for an electronic device as claimed in claim 1, wherein, a slide way is provided in the frame of the lid and a push key is provided in the slide way; the primary magnet being fixed in a section in the lid where the push key being embedded; and the attachment and the secondary magnet being relatively embedded inside the case.

3. A magnetic open/close structure for an electronic device as claimed in claim 1, wherein, a slide way is preset in the case and the push key is provided inside the slide way; the primary magnet being fixed in a section in the case where the push key being embedded; and the attachment and the secondary magnet being relatively embedded inside the lid.

4. A magnetic open/close structure for an electronic device as claimed in claim 1, wherein, the attachment is related to a piece of galvanized steel.

5. A magnetic open/close structure for an electronic device as claimed in claim 2, wherein, the case is comprised of an upper case cover bound to the lid and the attachment and the secondary magnet are fixed to the inner side of the upper cover of the case by means of a consistent binding process including fusion and locking.

6. A magnetic open/close structure for an electronic device as claimed in claim 3, wherein, the lid is provided with a front frame to be bound to the case and the attachment and the secondary magnet are fixed to the inner side of the front frame of the lid by means of a consistent binding process including fusion and locking.

7. A magnetic open/close structure for an electronic device as claimed in claim 2, wherein, a recess is provided to the push key to catch and hold in position the primary magnet in the section of the lid where the push key is embedded.

8. A magnetic open/close structure for an electronic device as claimed in claim 3, wherein, a recess is provided to the push key to catch and hold in position the primary magnet in the section of the case where the push key is embedded.

9. A magnetic open/close structure for an electronic device as claimed in claim 2, wherein, multiple primary magnets are fixed in the recess inside the lid at where the push key is embedded and multiple secondary magnets in the same quantity as that of the primary magnets are provided inside the case.

10. A magnetic open/close structure for an electronic device as claimed in claim 3, wherein, multiple primary magnets are fixed in the recess inside the case at where the push key is embedded and multiple secondary magnets in the same quantity as that of the primary magnets are provided inside the lid.

11. A magnetic open/close structure for an electronic device as claimed in claim 1, wherein, a face panel of the case is made of a metallic material to constitute the attachment; the primary magnet being provided to the frame of the lid; a specific local part to the frame of the case at where relatively to the location of the primary magnet being magnetized to define a magnetized area to constitute a secondary magnet mutually inductive to the primary magnet.
